(19) United States
(12) Patent Application Publication
(10) Pub. No.: US 2009/0308429 A1
(43) Pub. Date: Dec. 17, 2009

(54) THIN-FILM SOLAR MODULE

(75) Inventors: Timothy Michael Walsh, Watsonia Victoria (AU); Armin Gerhard Aberle, Singapore (SG)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NEWSOUTH INNOVATIONS PTY LIMITED, University of New south Wales (AU)

(21) Appl. No.: 12/438,338

(22) PCT Filed: Aug. 21, 2007
(86) PCT No.: PCT/AU2007/001197

§ 371 Date: Apr. 9, 2009

(30) Foreign Application Priority Data
Aug. 22, 2006 (AU) 2006904568

(51) Int. Cl. H01L 31/042; H01L 31/18

(52) U.S. Cl. 136/244; 438/97; 257/E21.211

(57) ABSTRACT

A thin-film solar cell module and a method of interconnecting thin-film solar cells are described. The method comprises forming one or more grooves (200) in a semiconductor thin-film diode structure (202) on a superstrate (102) such that the diode structure is divided into a plurality of discrete solar cells (206), and such that pairs of sidewalls (204) of the respective solar cells have a doping polarity that is the same as that of a superstrate-side semiconductor layer of the diode structure. A non-continuous insulating layer (300) is formed on the diode structure such that one sidewall of each pair of sidewalls is covered by the insulating layer while the other sidewall of each pair and one or more surface contact regions of each solar cell remain exposed. A non-continuous conductive layer (400) is formed on the diode structure such that for each pair of adjacent first and second solar cells (206a, 206b), the exposed sidewall of the first solar cell is electrically connected to the surface contact regions of the second solar cell and remains free from electrical connection to the surface contact regions of the first solar cell.

### FIELD OF INVENTION

The present invention relates broadly to a method of interconnecting thin-film solar cells, and to a thin-film solar cell module.

### BACKGROUND

Thin-film solar cells on a supporting foreign superstrate (such as glass) have the potential to dramatically reduce the cost of manufacture of solar photovoltaic (PV) modules due to the fact that they only require a fraction of the semiconductor material as compared to traditional, wafer-based solar cells. Thin-film solar cells, furthermore, have the advantage that it is possible to manufacture them on large-area substrates (˜1 m²), streamlining the production process and further reducing processing costs.

Whilst the output current of a solar cell scales with device size, the output voltage does not, and hence large-area (˜1 m²) solar cells have a very high current and a low voltage. Since resistive losses are proportional to the square of the current, large-area solar cells have large resistive losses (and hence low energy conversion efficiency) and are thus unsuited for most applications. The usual way to overcome this problem is to divide the large-area solar cell into many (say k) smaller cells, each having the same size, and to electrically interconnect the smaller cells in series, so that the voltages of the respective cells add up, and the current of the cells is only 1/kth of the current of the large-area cell.

Most solar cells are based on a p-n junction semiconductor diode. With silicon wafer based solar cells this diode structure is usually realized by using a uniformly doped p-type wafer and by forming (for instance by diffusion) a thin, n⁺-type layer along one surface of the wafer. With thin-film solar cells, the diode structure is usually created in-situ as the thin semiconductor film is deposited. The resulting p-n junction diode structure is typically less than 5 microns in thickness, compared to several hundred microns for silicon wafer solar cells.

The series interconnection of solar cells involves electrically connecting (through a suitable conducting medium such as a metal) the n-type side of one p-n junction diode (or cell) to the p-type side of the next cell, and so on. Current can then be extracted from the string of cells by connecting the p-type side of the first cell and the n-type side of the last cell to a load. If all the individual cells in the string are of the same size, then the current produced by each cell will be the same and equal to the current through the entire string of cells. The output voltage from each cell will add to the voltages of the other cells in the string, so that if there are k cells in the string each having a voltage V, then the resulting output voltage of the whole string will be k×V (ignoring resistive losses).

With solar cells made from silicon wafers, this series interconnection is typically done wafer by wafer, as the wafers are built into a module. With thin-film solar cells a different approach is typically used since, as mentioned earlier, thin-film solar cells have the advantage of being able to be deposited onto large-area substrates.

One typical way to interconnect thin-film solar cells on glass superstrates is based on the use of transparent conductive oxides (TCOs) such as indium tin oxide or zinc oxide. These TCOs are basically high-bandgap semiconductors that do not absorb a significant amount of sunlight but nevertheless, due to the fact that they are heavily doped, are good electrical conductors. TCOs are a crucial component of PV modules made from semiconductors that do not exhibit a satisfactory lateral conductance (i.e., the doped semiconductor layers have a very high electrical sheet resistance). PV modules made from poorly conductive semiconductors (such as amorphous or microcrystalline silicon) usually use two TCO films on the solar cells—one on the front surface and one on the back surface. The interconnection of adjacent cells is realised by a combination of laser scribing and sequential deposition of individual TCO or semiconductor layers.

If the semiconductor layers have a sufficiently good lateral electrical conductance, then the use of TCOs can be avoided, and instead the semiconductor can directly be contacted by grid or stripe-like metal contacts. Patent Publication No. WO 03/019674 A1 by Basore et alia describes a possible interconnect scheme for such thin-film solar cells. Another possible scheme is described by Wenham et al. in their U.S. Pat. No. 5,595,607. This scheme is based on grooves whose sidewalls are heavily doped in a particular process sequence and subsequent filling of the grooves with metal.

In the context of a production environment, the above-mentioned interconnection schemes for semiconductor layers having a sufficiently good lateral electrical conductance require a significant number of processing steps to achieve the interconnection. A need therefore exists to provide an alternative technique for interconnecting thin-film solar cells on foreign superstrates that seeks to address that problem.

### SUMMARY

In accordance with a first aspect of the present invention there is provided a method of interconnecting thin-film solar cells, the method comprising the steps of forming one or more grooves in a semiconductor thin-film diode structure on a superstrate such that the diode structure is divided into a plurality of discrete solar cells, and such that pairs of sidewalls of the respective solar cells have a doping polarity that is the same as that of a superstrate-side semiconductor layer of the diode structure; forming a non-continuous insulating layer on the diode structure such that one sidewall of each pair of sidewalls is covered by the insulating layer while the other sidewall of each pair and one or more surface contact regions of each solar cell remain exposed; and forming a non-continuous conductive layer on the diode structure such that for each pair of adjacent first and second solar cells, the exposed sidewall of the first solar cell is electrically connected to the surface contact regions of the second solar cell and remains free from electrical connection to the surface contact regions of the first solar cell.

The grooves may be formed by laser scribing.

Forming the non-continuous insulating layer, conductive layer, or both, may comprise ink-jet printing.

Forming the non-continuous insulating layer, conductive layer, or both, may comprise screen printing.

Forming the non-continuous insulating layer, conductive layer, or both, may comprise patterning the respective layers during or after deposition of materials for the respective layers.

Patterning the respective layers after the deposition of the materials for the respective layers may comprise ink-jet printing or photolithography.

The non-continuous insulating layer may comprise a polymer.

The non-continuous conductive layer may comprise a metal paste.

The diode structure may comprise polycrystalline silicon.

The method may further comprise providing an anti-reflective coating between the superstrate and the diode structure.

In accordance with a second aspect of the present invention there is provided a thin-film solar module comprising a superstrate; a semiconductor thin-film diode structure formed on the superstrate; one or more grooves formed in the diode structure such that the diode structure is divided into a plurality of discrete solar cells, and such that pairs of sidewalls of the respective solar cells have a doping polarity that is the same as that of a superstrate-side semiconductor layer of the diode structure; a non-continuous insulating layer on the diode structure such that one sidewall of each pair of sidewalls is covered by the insulating layer while the other sidewall of each pair and one or more surface contact regions of each solar cell remain exposed; and a non-continuous conductive layer on the diode structure such that for each pair of adjacent first and second solar cells, the exposed sidewall of the first solar cell is electrically connected to the surface contact regions of the second solar cell and remains free from electrical connection to the surface contact regions of the first solar cell.

The non-continuous insulating layer may comprise a polymer.

The non-continuous conductive layer may comprise a metal paste.

The diode structure may comprise polycrystalline silicon.

The module may further comprise an anti-reflective coating between the superstrate and the diode structure.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic cross-sectional drawing of an asymmetrically doped solar cell structure.

FIGS. 2 to 4 are schematic cross-sectional drawings illustrating a method of interconnecting thin-film solar cells.

FIG. 5 is a schematic plan view of a solar module.

FIG. 6 shows a flowchart illustrating a method of interconnecting thin-film solar cells.

### DETAILED DESCRIPTION

The embodiments described provide a method for interconnecting thin-film solar cells on glass (or other insulating, transparent foreign materials) which have a sufficiently good lateral electrical conductance. In particular, the method will be described in the context of solar cells having one p-n junction, but it will be appreciated by a person skilled in art that, with suitable modification, the method can also be applied to multi-junction solar cells.

The solar cells consist of a lightly doped (or intrinsic) absorber region sandwiched between two heavily doped layers of opposite polarity. The solar cells are thus of the type n⁺πp⁺, whereby π stands for a layer of p (positive), n (negative) or i (intrinsic) type semiconductor material. The method can be applicable to both n⁺πp⁺/glass and p⁺πn⁺/glass structures, or equivalent structures with insulating supporting superstrates which are largely transparent in the visible spectrum. The π layer is typically less than 10 microns thick and thus has a negligible lateral conductance compared to the p⁺ and n⁺ layers. The transparent superstrate may also have an anti-reflection layer on the surface facing the solar cells. This anti-reflective layer is typically made from silicon nitride.

The method can apply to asymmetrically doped solar cells where the dopant dose in the glass-side heavily doped layer is at least several times greater than the dopant dose in the air-side heavily doped layer, such that when the semiconductor film is locally melted (for example by a laser), the dopant species will diffuse throughout the melted semiconductor region and p-type and n-type dopants partially compensating each other, so that the final doping polarity of the melted region will be the same as that of the glass-side heavily doped layer.

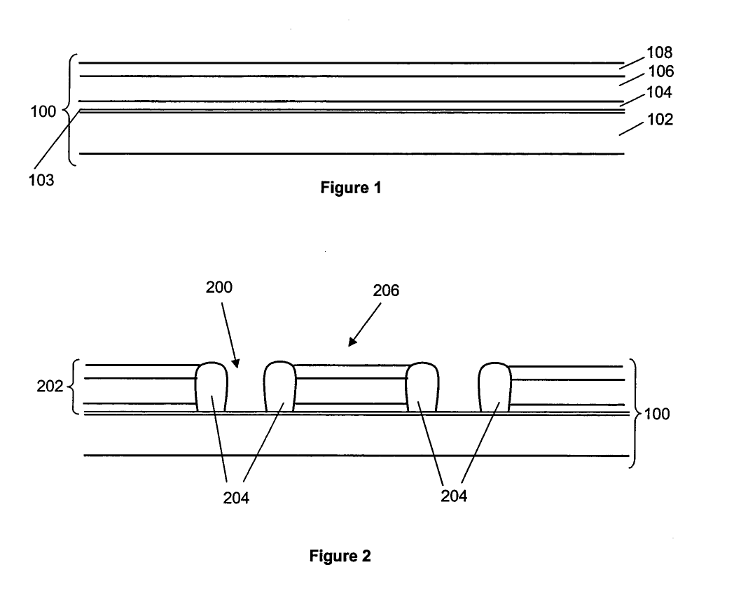

FIG. 1 shows a schematic cross sectional view of an example asymmetrically doped solar cell structure 100. The structure 100 comprises a glass supporting superstrate 102, which although in the pictures is drawn at the bottom of the structure, is actually the surface which faces the sun. The glass superstrate 102 has an anti-reflective layer or coating 103 made form silicon nitride in the example embodiment. A glass-side heavily doped n⁺ layer 104 is formed of a thickness of about 50-200 nm. A lightly doped p layer 106 of a thickness of about 1-10 microns, and a heavily doped p⁺ layer 108 of a thickness of about 50-200 nm complete the p⁺pn⁺ /glass solar cell structure 100. The semiconductor layers 104, 106 and 108 are formed utilising in-situ doping techniques during thin-film semiconductor material deposition onto the glass superstrate 102. The semiconductor material may comprise polycrystalline silicon deposited using, for example, plasma-enhanced chemical vapour deposition (PECVD) or electron beam evaporation, and utilising, for example, boron and phosphorus for the positive and negative doping respectively.

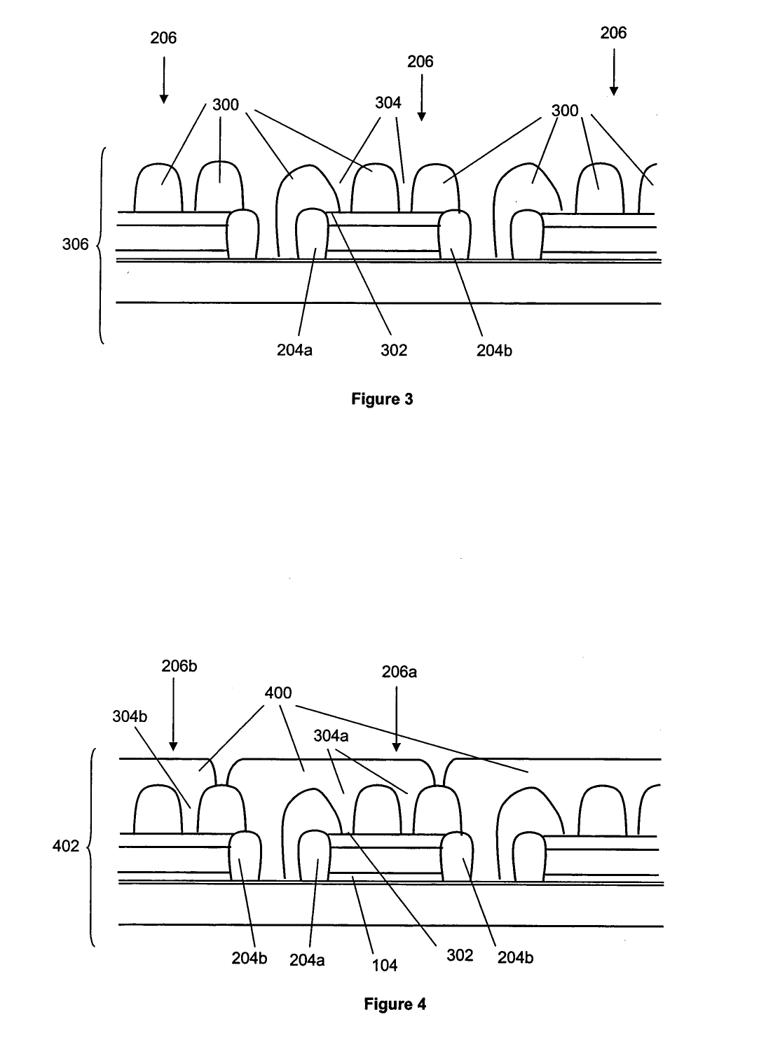

In a first step for monolithically interconnecting smaller cells of the large-area solar cell structure 100, a set of parallel grooves 200 is scribed into the semiconductor film 202 containing the layers 104, 106 and 108, using a laser, separating the large-area solar cell structure 100 into k long, narrow solar cells 206, as illustrated in FIG. 2. In the example embodiment shown the anti-reflective layer 103 is not scribed by the laser beam, however, the method has been shown to work equally well if the anti-reflective layer is scribed by the laser beam. Due to the asymmetric doping structure of the precursor thin-film solar cell 100, the laser-scribed sidewalls 204 of the long, narrow solar cells 206 will have the same doping polarity as the superstrate-side heavily doped layer 104 of the cells 206, i.e. n in the described example.

When a pulse of light from the laser hits the semiconductor film 202, some fraction of the incident light is absorbed, causing the film 202 to heat up. Since the absorption coefficient of the film 202 increases with temperature, more of the laser light is absorbed as the film 202 heats. This leads to a situation known as thermal runaway, where the film 202 quickly reaches boiling temperature. The portion of the semiconductor film 202 under the centre of the laser beam, where it is most intense, reaches boiling point first, while the portions of the semiconductor film 202 under the periphery of the laser beam only reach melting point. The portion of the semiconductor film 202 under the centre of the laser beam vaporises, expanding rapidly as it does so. This rapid expansion of semiconductor vapour pushes aside the molten semiconductor away from the centre of the laser-treated region, forming the grooves 200.

The molten semiconductor material cools and resolidifies as it is being pushed away such that it is frozen in a wavelike shape, forming the sidewalls 204. The diffusion of dopant atoms in the liquid phase semiconductor material is so rapid that the dopants are spread uniformly throughout the melted and resolidified portions of the semiconductor film 202. This process happens very rapidly, in the duration of a single laser pulse. By overlapping successive pulses as the laser beam is scanned across the semiconductor film 202 surface, the groove 200 can be scribed in the semiconductor film 202.

Next, a non-continuous insulating layer 300 is applied to the surface of the solar cells 206, for example by ink-jet or screen printing, such that one sidewall 204a and a substantial portion of the surface 302 of each cell 206 is covered by the insulator 300, but the other sidewall 204b of each cell 206, as well as several “contact regions” 304 on the surface 302 of each cell 206 are left uncovered by the insulator 300, as shown in FIG. 3. The insulating layers 300 may for example comprise a polymer such as polyimide. The insulating layer 300 is then dried by, for example, baking the device 306 at a moderate temperature. Thermal oxide from the exposed laser-scribed sidewalls 204b, and the native oxide from the surface contact regions 304 are then removed, for example by etching in hydrofluoric acid.

Next, a non-continuous conductive layer 400, for example metal, is applied by, for example, screen or ink-jet printing, as shown in FIG. 4. The conductive layer 400 is applied such that, for each pair of adjacent cells 206a, 206b, an electrically conductive path is provided between the exposed sidewall 204b of one solar cell 206b and the contact regions 304a of the adjacent solar cell 206a, but that there is no electrically conductive path between the exposed sidewall 204b and the contact regions 304b of the same cell 206b. The metal layer 400 is also non-continuous along the length of the long, narrow solar cells 206a, b, so that a possible local shunt along the solar cell 206a, b will not collect current from the entire solar cell 206a, b area, but only from the area immediately surrounding the shunt. The device 402 is then baked at a moderate temperature to improve the electrical properties of the metal-semiconductor contacts.

The device 402 provides a thin-film solar cell module comprising the superstrate 102 and a semiconductor thin-film diode structure formed on the superstrate with one or more grooves formed in the diode structure such that the diode structure is divided into a plurality of discrete solar cells 206a, b, and such that pairs of sidewalls 204a, b, of the respective solar cells have a doping polarity that is the same as that of a superstrate-side semiconductor layer 104 of the diode structure. The module further comprises a non-continuous insulating layer 300 on the diode structure such that one sidewall 204a of each pair of sidewalls is covered by the insulating layer 300 while the other sidewall 204b of each pair and one or more surface contact regions e.g. 304a of each solar cell e.g. 206a remain exposed. The module further comprises a non-continuous conductive layer 400 on the diode structure such that for each pair of adjacent first and second solar cells 206b, a, the exposed sidewall 204b of the first solar cell 206b is electrically connected to the surface contact regions 304a of the second solar cell 206a and remains free from electrical connection to the surface contact regions 304b of the first solar cell 206b.

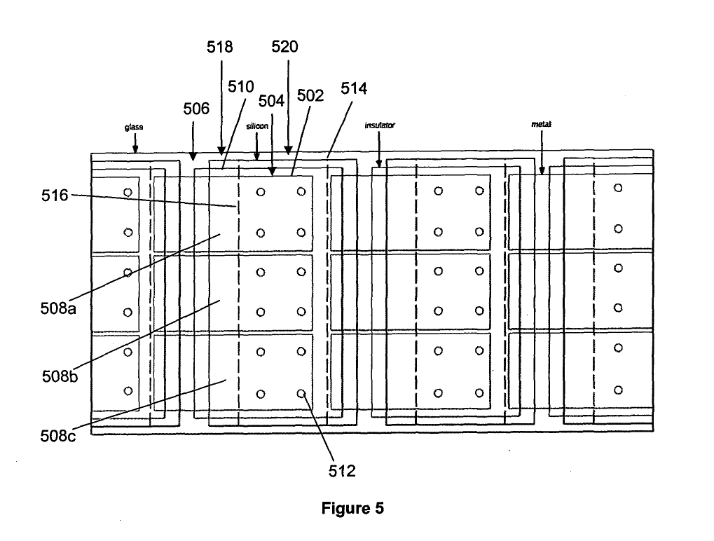

FIG. 5 shows a schematic plan view of a device 500 formed in accordance with the method described above with reference to FIGS. 1 to 4. The outer metal layer 502 is formed as discontinuous rows 504 along the grooves 506, and each row 504 is also discontinuous along the length of the grooves 506, forming segments 508a to c along the grooves 506. Within the insulating layers 510, openings 512 are formed, which are filled with material from the metal layer 504 for contacting the surface of each semiconductor cell 514. The broken lines 516 within the semiconductor layers 514 indicate the boundary between sidewalls 518 of the grooves 506, and the remaining solar cell portions 520.

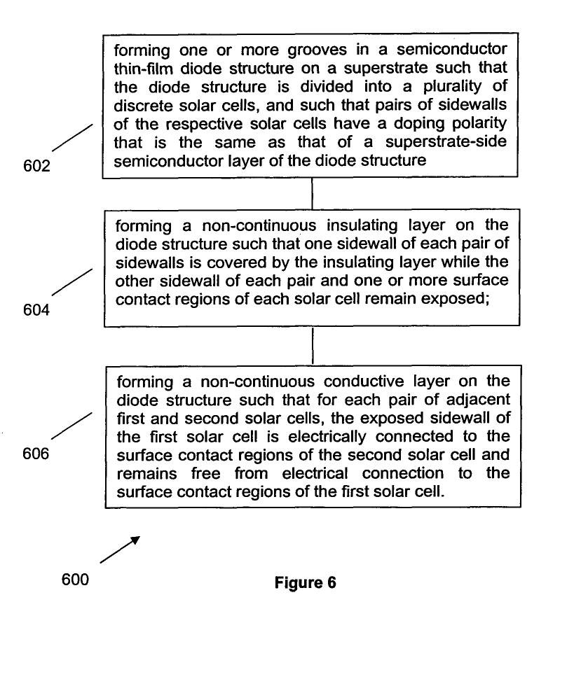

FIG. 6 shows a flowchart 600 illustrating a method of interconnecting thin-film solar cells. At step 602, one or more grooves are formed in a semiconductor thin-film diode structure on a superstrate such that the diode structure is divided into a plurality of discrete solar cells, and such that pairs of sidewalls of the respective solar cells have a doping polarity that is the same as that of a superstrate-side semiconductor layer of the diode structure. At step 604, a non-continuous insulating layer is formed on the diode structure such that one sidewall of each pair of sidewalls is covered by the insulating layer while the other sidewall of each pair and one or more surface contact regions of each solar cell remain exposed. At step 606, a non-continuous conductive layer is formed on the diode structure such that for each pair of adjacent first and second solar cells, the exposed sidewall of the first solar cell is electrically connected to the surface contact regions of the second solar cell and remains free from electrical connection to the surface contact regions of the first solar cell.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, while the solar cell structure described is a glass/n⁺/p/p⁺ structure with n-type sidewalls, it is to be understood that this particular doping structure is by way of example only and is not intended to be restrictive. Also, the particular layout of surface contacts depicted is only by way of example.

Furthermore, it will be appreciated that the non-continuous insulating layer, conductive layer, or both, may be applied as a continuous layer, and subsequently patterned using for example ink-jet printing or photolithography, to form the respective non-continuous layers.

It is also noted here that the drawings in FIGS. 1 to 5 are schematic drawings only and are not to scale.

1-15. (canceled)

16. A method of interconnecting thin-film solar cells, the method comprising the steps of:
forming one or more grooves in a semiconductor thin-film diode structure on a superstrate such that the diode structure is divided into a plurality of discrete solar cells, and such that pairs of sidewalls of the respective solar cells have a doping polarity that is the same as that of a superstrate-side semiconductor layer of the diode structure;
forming a non-continuous insulating layer on the diode structure such that one sidewall of each pair of sidewalls is covered by the insulating layer while the other sidewall of each pair and one or more surface contact regions of each solar cell remain exposed; and
forming a non-continuous conductive layer on the diode structure such that for each pair of adjacent first and second solar cells, the exposed sidewall of the first solar cell is electrically connected to the surface contact regions of the second solar cell and remains free from electrical connection to the surface contact regions of the first solar cell.

17. The method as claimed in claim 16, wherein the grooves are formed by laser scribing.

18. The method as claimed in claim 16, wherein forming the non-continuous insulating layer, conductive layer, or both, comprises ink-jet printing.

19. The method as claimed in claim 16, wherein forming the non-continuous insulating layer, conductive layer, or both, comprises screen printing.

20. The method as claimed in claim 16, wherein forming the non-continuous insulating layer, conductive layer, or both, comprises patterning the respective layers during or after deposition of materials for the respective layers.

21. The method as claimed in claim 20, wherein patterning the respective layers after the deposition of the materials for the respective layers comprises ink-jet printing or photolithography.

22. The method as claimed in claim 16, wherein the non-continuous insulating layer comprises a polymer.

23. The method as claimed in claim 16, wherein the non-continuous conductive layer comprises a metal paste.

24. The method as claimed in claim 16, wherein the diode structure comprises polycrystalline silicon.

25. The method as claimed in claim 16, further comprising providing an anti-reflective coating between the superstrate and the diode structure.

26. A thin-film solar module comprising:
a superstrate;
a semiconductor thin-film diode structure formed on the superstrate;
one or more grooves formed in the diode structure such that the diode structure is divided into a plurality of discrete solar cells, and such that pairs of sidewalls of the respective solar cells have a doping polarity that is the same as that of a superstrate-side semiconductor layer of the diode structure;
a non-continuous insulating layer on the diode structure such that one sidewall of each pair of sidewalls is covered by the insulating layer while the other sidewall of each pair and one or more surface contact regions of each solar cell remain exposed; and
a non-continuous conductive layer on the diode structure such that for each pair of adjacent first and second solar cells, the exposed sidewall of the first solar cell is electrically connected to the surface contact regions of the second solar cell and remains free from electrical connection to the surface contact regions of the first solar cell.

27. The module as claimed in claim 26, wherein the non-continuous insulating layer comprises a polymer.

28. The module as claimed in claim 26, wherein the non-continuous conductive layer comprises a metal paste.

29. The module as claimed in claim 26, wherein the diode structure comprises polycrystalline silicon.

30. The module as claimed in claim 26, further comprising an anti-reflective coating between the superstrate and the diode structure.
